(19) United States
(12) Patent Application Publication
(10) Pub. No.: US 2022/0134423 A1
(43) Pub. Date: May 5, 2022

(54) LOW TEMPERATURE-SINTERING REAR SILVER PASTE FOR ALL-ALUMINUM BACK SURFACE FIELD CRYSTALLINE SILICON SOLAR CELL

(71) Applicant: NANTONG T-SUN NEW ENERGY CO., LTD., Nantong (CN)

(72) Inventors: Peng ZHU, Nantong (CN); Guizhong YANG, Nantong (CN); Yanmei CHEN, Nantong (CN); Yeqing WANG, Nantong (CN)

(21) Appl. No.: 17/431,382

(22) PCT Filed: Jul. 12, 2019
(86) PCT No.: PCT/CN2019/095754

§ 371 Date: Aug. 16, 2021

(30) Foreign Application Priority Data
Jun. 19, 2019 (CN) 201910529059.2

(51) Int. Cl. B22F 1/107; B22F 1/05; H01L 31/0224; H01L 31/18

(52) U.S. Cl. CPC B22F 1/107; B22F 1/05; B22F 2304/10; H01L 31/1868; B22F 2301/255; H01L 31/022425

(57) ABSTRACT

A low temperature-sintering rear silver paste for an all-aluminum back surface field crystalline silicon solar cell includes the following components in part by mass: 50-70 parts of a nano-silver powder, 20-50 parts of an organic vehicle, 0.1-0.3 parts of a dispersant and 0.1-0.3 parts of a thixotropic agent. The nano-silver powder adopted in the present invention has good sintering activity, and thus is suitable for sintering at low temperature. In addition, part of the silver paste will permeate into a rear aluminum paste in the process of sintering to form good silver-aluminum contact.

### TECHNICAL FIELD

The present invention relates to the field of macromolecule-based conductive materials and, in particular, to a low temperature-sintering rear silver paste for an all-aluminum back surface field crystalline silicon solar cell.

### BACKGROUND

With the rapid development of modern industry, the natural energy resources such as petroleum, coal and natural gas on the earth are gradually depleted, and the subsequent energy crisis, greenhouse effect and environmental pollution are increasingly serious, which poses the need for seeking novel clean energy resources capable of replacing the natural energy resources. The sun has become an effective provider of novel energy sources. Solar energy can be converted into electric energy by solar cells, which is the most direct way to convert solar energy with the least steps among all the methods for utilizing clean energy sources.

Solar cells available on the market are mainly crystalline silicon solar cells at present, and in consideration of technical maturity, photoelectric conversion efficiency, sources of starting materials and the like, silicon solar cells will remain the main focus of development of photovoltaic solar cells for a long time in the future. Therefore, how to further improve the photoelectric conversion efficiency of crystalline silicon solar cells is one of the continuous pursuits in the industry.

Aluminum back surface field (BSF) is a typical back surface passivation structure commonly employed in modern crystalline silicon solar cells. After years of development, the production process of the aluminum back surface field gradually tends to be mature and stable, and various studies on the aluminum back surface field are increasingly deepened. All those above indicate that the aluminum back surface field will remain to be widely used for crystalline silicon solar cells in a long time in the future and to be a major contribution to improving the conversion efficiency of cells.

Therefore, the preparation process flow of a conventional crystalline silicon solar cell at present comprises performing diffusion on the starting material, a silicon die, to prepare p-n junctions after pre-cleaning and texturing, removing the phosphorosilicate glass (PSG) layer by etching, plating an anti-reflection coating to give a blue film plate by PECVD, printing a rear silver paste to prepare rear silver electrodes by screen printing, printing a rear aluminum paste to prepare the aluminum back surface field after drying, printing a front silver paste to prepare front silver electrodes after drying, and sintering at high temperature for a short time after drying to give a cell plate.

In addition to properties of good printing performance and a low silver content required for a conventional crystalline silicon cell rear silver paste, the requirements of the PERC cell on the PERC rear silver paste further comprise the following: (1) low activity to reduce the reaction of the glass powder with the passivation coating, to prevent a large number of recombination centers from forming at the place where the silver paste contacts with the silicon die, and to improve the open-circuit voltage; (2) a wide process window suitable for the low temperature-sintering process; and (3) excellent adhesion and aging adhesion.

Chinese Patent CN109659068A discloses a low temperature-curing rear silver paste for an all-aluminum back surface field crystalline silicon solar cell, prepared from 10-20 parts of a spherical silver powder, 50-60 parts of a flake silver powder, 14-30 parts of bisphenol A epoxy resin, 5-9.6 parts of a reactive diluent, 0.77-1.18 parts of curing agent dicyandiamide, 0.02-0.04 parts of a curing accelerator and 0.2-0.5 parts of a thixotropic auxiliary agent. However, the rear electrode printed with the low temperature-curing rear silver paste of the invention has poor adhesion, resulting in reduced open voltage of the PERC solar cell and thus reduced photoelectric conversion efficiency of the PERC solar cell.

### SUMMARY

In order to solve the above problems, the present invention provides a low temperature-sintering rear silver paste for an all-aluminum back surface field crystalline silicon solar cell for reducing recombination of current carriers and formation of silver-aluminum alloy. The process of the silver paste features simplified procedures and is suitable for the existing process flow. The technical scheme of the present invention is as follows:

The present invention provides a low temperature-sintering rear silver paste for an all-aluminum back surface field crystalline silicon solar cell, comprising the following components in part by mass:

| | | | |
|---|---|---|---|
| i. | a nano-silver powder | 60-70 | parts; |
| ii. | an organic vehicle | 20-45 | parts; |
| iii. | a dispersant | 0.1-0.3 | parts; and |
| iv. | a thixotropic agent | 0.1-0.3 | parts; |

wherein the nano-silver powder has a tap density of 3-3.5 g/cm³, a specific surface area of 4.8-5.8 cm²/g, a median particle size D₅₀ of 0.05-0.5 μm, a span of the particle size of 0.8-0.9, and a loss on ignition of 0.1-0.2%.

In some embodiments of the present invention, the low temperature-sintering rear silver paste further comprises 1-10 parts by mass of a glass powder.

In some embodiments of the present invention, the glass powder is a lead-free glass powder, and has a softening temperature of 500-700° C. and an average particle size D₅₀ of 0.3-0.4 μm. ( [symbol] )

In some embodiments of the present invention, the glass powder comprises, in part by mass, 60-65 parts of Bi₂O₃, 20-30 parts of B₂O₃, 5-10 parts of ZnO or Zn₃(PO₄)₂, 20-25 parts of SiO₂, 1-3 parts of Al₂O₃, 5-10 parts of NiO and 2-5 parts of V₂O₅.

In some embodiments of the present invention, the organic vehicle is selected from ethyl cellulose, terpineol, butyl carbitol, butyl carbitol acetate and texanol, or a mixture thereof.

In some embodiments of the present invention, the dispersant is selected from DMA, TDO, sorbitan trioleate, BYK-110 and BYK-111, or a mixture thereof.

DMA is dimethylacetamide, or N,N-dimethylacetamide (chemical formula: CH₃C(O)N(CH₃)₂; abbreviated as DMAC or DMA); DMA is commonly used as an aprotic polar solvent in the form of a colorless, transparent and flammable liquid. It is miscible with organic solvents such as water, alcohol, ether, ester, benzene, chloroform and aromatic compounds, suitable for preparing medicines and synthesizing resins, and also used as a solvent for spinning polyacrylonitrile and as an extraction and distillation solvent for separating styrene from a C8 fraction. It is prepared by the reaction of dimethylamine and acetyl chloride.

TDO is a special dual-ion long-chain super wetting dispersant, and is suitable for preparing various aqueous and oily organic and inorganic coating pastes. As TDO has high surface activity, it has remarkable performance. TDO enables the paste to migrate during the curing process of the painted coating and to firmly adhere to a solid surface, so as to give an ideal effect.

BYK-110 deflocculates the paste by steric hindrance. High gloss and increased color intensity can be provided due to the low particle size in the deflocculated paste. In addition, transparency and hiding power are increased. Such products have reduced viscosity and thus improved leveling property. Therefore, the paste content can be increased.

BYK-111 is a solvent-free wetting dispersant for solvent-based and solvent-free pastes and printing inks, and can stabilize inorganic pigments, especially titanium dioxide. The viscosity of the grinding material is significantly reduced.

In some embodiments of the present invention, the thixotropic agent is selected from hydrogenated castor oil and polyamide wax, or a mixture thereof.

The present invention further provides a method for preparing a rear silver electrode of a PERC solar cell by using the low temperature-sintering rear silver paste for an all-aluminum back surface field crystalline silicon solar cell disclosed herein, comprising forming a silicon nitride anti-reflection passivation coating on a front of a P-type crystalline silicon, plating a rear passivation layer on a rear of the P-type crystalline silicon, grooving on the rear passivation layer, and metallizing the front and the rear of the P-type crystalline silicon, wherein metallizing the rear of the P-type crystalline silicon comprises the following steps:

printing an aluminum paste on the rear passivation layer of the P-type crystalline silicon and drying, then printing a silver paste on the front and drying, and sintering; and

printing the low temperature-sintering rear silver paste on the rear aluminum paste according to the step (1), drying and sintering to form a rear silver electrode.

In some embodiments of the present invention, for the rear aluminum paste in step (1) above, the drying temperature is 150-250° C., and the drying time period is 2.5-3.5 min; for the front silver paste, the drying temperature is 150-250° C., the sintering temperature is 750-850° C., and the sintering time period is 8-15 s.

In some embodiments of the present invention, for the rear electrode in step (2) above, the drying temperature is 150-250° C., the drying time period is 1.5-2.5 min, the sintering temperature is 250-400° C., the width is 0.6-2.5 mm, the length is 8-20 mm, and the height is 2-5 μm.

Beneficial Effects: The present invention has the following advantages:

Printing the low temperature-sintering rear silver paste for an all-aluminum back surface field crystalline silicon solar cell disclosed herein on a PERC solar cell can effectively prevent silver and aluminum from mutual diffusion to form silver-aluminum alloy and the welding performance can be improved; the rear silver paste is printed on the rear aluminum layer to form a layer in the rear silver region, which can increase the contact area between the rear silver paste and the aluminum paste, thereby increasing the open-circuit voltage of the solar cell prepared, reducing the lap resistance of silver and aluminum and thus improving the photoelectric conversion efficiency of the cell.

The nano-silver powder in the low temperature-sintering rear silver paste for an all-aluminum back surface field crystalline silicon solar cell disclosed herein has a tap density of 3-3.5 g/cm³, specific surface area of 4.8-5.8 cm²/g, a median particle size D₅₀ of 0.05-0.5 μm, a span of the particle size of 0.8-0.9, and a loss on ignition of 0.1-0.2%. The nano-silver powder adopted in the present invention has good sintering activity, and thus is suitable for sintering at low temperature. In addition, part of the silver paste will permeate into a rear aluminum paste in the process of sintering to form good silver-aluminum contact.

The low temperature-sintering rear silver paste for an all-aluminum back surface field crystalline silicon solar cell disclosed herein can be used for preparing rear silver electrodes, wherein the low temperature-sintering rear silver paste is printed on the all-aluminum rear. By using the method of preparing the rear electrode, a complete BSF layer can be formed, leading to an improved field passivation property of electrode regions and reduced carrier recombination. Besides, no silver entering a silicon substrate avoids electric leakage, thereby reducing leakage current in cells and improving the photoelectric conversion efficiency. Compared to a conventional paste, eliminated need for overprinting process reduces the width of the electrode and thus the costs.

### DETAILED DESCRIPTION

The technical schemes in the embodiments of the present invention will be clearly and completely described below, for a better understanding of the advantages and features of the present invention by those skilled in the art, and for a more the clearly defined protection scope of the present invention. The described embodiments are only some, but not all, embodiments of the invention. Based on the embodiments of the present invention, all other embodiments obtained by those of ordinary skill in the art without making any creative effort will fall within the protection scope of the present invention.

### Example 1

1. Preparation of Low Temperature-Sintering Rear Silver Paste

The present invention provides a low temperature-sintering rear silver paste for an all-aluminum back surface field crystalline silicon solar cell for reducing recombination of current carriers and formation of silver-aluminum alloy, the process of which features simplified procedures and is suitable for the existing process flow. The low temperature-sintering rear silver paste was prepared from the following components in part by mass:

| | | | |
|---|---|---|---|
| i. | a nano-silver powder | 63 | parts; |
| ii. | ethyl cellulose | 26.6 | parts; |
| iii. | butyl carbitol | 10 | parts; |
| iv. | DMA | 0.1 | parts; |
| v. | BYK-110 | 0.1 | parts; and |
| vi. | hydrogenated castor oil | 0.2 | parts; |

wherein the nano-silver powder has a tap density of 3.25 g/cm³, a specific surface area of 5 cm²/g, a median particle size D₅₀ of 0.275 μm, a span of the particle size of 0.85, and a loss on ignition of 0.15%. The above nano-silver powder, ethyl cellulose, butyl carbitol, DMA, BYK-110 and hydrogenated castor oil were well mixed according to the ratios, and ground and dispersed such that the fineness of the paste did not exceed 15 μm.

2. Preparation of Rear Electrode of PERC Solar Cell

Metallization of the rear electrode was performed by using the low temperature-sintering rear silver paste prepared above. Double-sided texturing was first performed on the front and the rear of a P-type crystalline silicon by using acid or base;

a silicon nitride anti-reflection passivation coating was then formed on the front of the P-type crystalline silicon;

a rear passivation layer was then plated on the rear of the P-type crystalline silicon, and by using SiNₓ or Al₂O₃ a passivation layer was formed on the rear of the cell as a rear reflector for increasing absorption of long wave light and for maximizing the potential difference between P-N electrodes to reduce electron recombination, so as to improve the conversion efficiency of the cell;

grooving was then performed on the rear passivation layer, and prior to metallization, coating opening following a specific pattern was performed on the rear passivation coating by using laser to remove part of the passivation layer; by using such local point contact mode, the electrode contact area and thus the electrode recombination could be reduced;

the front and the rear of the P-type crystalline silicon were then metallized separately, wherein the metallization of the rear of the P-type crystalline silicon comprised the following steps:
(1) an aluminum paste was printed on the rear passivation layer of the P-type crystalline silicon and dried, and the silver paste was then printed on the front, and dried and sintered, wherein for the rear aluminum paste, the drying temperature was 200° C., and the drying time period was 2 min; for the front silver paste, the drying temperature was 200° C., the drying time period was 2 min, the sintering temperature was 800° C., and the sintering time period was 11 s; and
(2) the low temperature-sintering rear silver paste was printed on the rear aluminum paste according to the step (1), dried and sintered to form a rear silver electrode, wherein for the above rear electrode, the drying temperature was 200° C., the drying time period was 2 min, the sintering temperature was 325° C., the width was 1.55 mm, the length was 14 mm, and the height was 3.5 μm.

### Example 2

1. Preparation of Glass Powder

65 parts of Pb₂O₃, 10 parts of B₂O₃, 5 parts of ZnO, 1 part of SiO₂, 1 part of Al₂O₃, 1 part of NiO and 2 parts of V₂O₅ were prepared. The materials were then well mixed using a known mixer such as a disperser or a three-roll mill, and dried for 3.5 h before being transferred into a crucible. The crucible containing the starting materials was first heated to 950° C. in a heating chamber, and then incubated for 1.5 h. The resultant liquid of the smelted materials was allowed to pass through a cooling roller to give a glass frit, which was then crushed and sieved to give the glass powder having a median particle size D₅₀ of 0.3 μm and a softening point of 350° C.

2. Preparation of Low Temperature-Sintering Rear Silver Paste

The present invention provides a low temperature-sintering rear silver paste for an all-aluminum back surface field crystalline silicon solar cell for reducing recombination of current carriers and formation of silver-aluminum alloy, the process of which features simplified procedures and is suitable for the existing process flow. The low temperature-sintering rear silver paste was prepared from the following components in part by mass:

| | | | |
|---|---|---|---|
| i. | a nano-silver powder | 60.4 | parts; |
| ii. | terpineol | 17 | parts; |
| iii. | butyl carbitol acetate | 17 | parts; |
| iv. | DMA | 0.15 | parts; |
| v. | BYK-111 | 0.15 | parts; |
| vi. | polyamide wax | 0.3 | parts; and |
| vii. | a glass powder | 5 | parts; |

wherein the nano-silver powder has a tap density of 3 g/cm³, a specific surface area of 4.8 cm²/g, a median particle size D₅₀ of 0.05 μm, a span of the particle size of 0.9, and a loss on ignition of 0.1%. The above nano-silver powder, terpineol, butyl carbitol acetate, DMA, BYK-111, polyamide wax and glass powder were well mixed according to the ratios, and ground and dispersed such that the fineness of the paste did not exceed 15 μm.

3. Preparation of Rear Electrode of PERC Solar Cell

Metallization of the rear electrode was performed by using the low temperature-sintering rear silver paste prepared above. Double-sided texturing was first performed on the front and the rear of a P-type crystalline silicon by using acid or base;

a silicon nitride anti-reflection passivation coating was then formed on the front of the P-type crystalline silicon;

a rear passivation layer was then plated on the rear of the P-type crystalline silicon, and by using SiNₓ or Al₂O₃ a passivation layer was formed on the rear of the cell as a rear reflector for increasing absorption of long wave light and for maximizing the potential difference between P-N electrodes to reduce electron recombination, so as to improve the conversion efficiency of the cell;

grooving was then performed on the rear passivation layer, and prior to metallization, coating opening following a specific pattern was performed on the rear passivation coating by using laser to remove part of the passivation layer; by using such local point contact mode, the electrode contact area and thus the electrode recombination could be reduced;

the front and the rear of the P-type crystalline silicon were then metallized separately, wherein the metallization of the rear of the P-type crystalline silicon comprised the following steps:
(1) an aluminum paste was printed on the rear passivation layer of the P-type crystalline silicon and dried, and the silver paste was then printed on the front, and dried and sintered, wherein for the rear aluminum paste, the drying temperature was 150° C., and the drying time period was 3.5 min; for the front silver paste, the drying temperature was 150° C., the drying time period was 3.5 min, the sintering temperature was 850° C., and the sintering time period was 8 s; and

the low temperature-sintering rear silver paste was printed on the rear aluminum paste according to the step (1), dried and sintered to form a rear silver electrode, wherein for the above rear electrode, the drying temperature was 150° C., the drying time period was 2.5 min, the sintering temperature was 250° C., the width was 0.6 mm, the length was 8 mm, and the height was 2 μm.

### Example 3

1. Preparation of Glass Powder

60 parts of Bi₂O₃, 20 parts of B₂O₃, 10 parts of Zn₃(PO₄)₂, 10 parts of SiO₂, 3 parts of Al₂O₃, 3 parts of NiO and 5 parts of V₂O₅ were prepared. The materials were then well mixed using a known mixer such as a disperser or a three-roll mill, and dried for 3.5 h before being transferred into a crucible. The crucible containing the starting materials was first heated to 1050° C. in a heating chamber, and then incubated for 1 h. The resultant liquid of the smelted materials was allowed to pass through a cooling roller to give a glass frit, which was then crushed and sieved to give the glass powder having a median particle size D₅₀ of 0.4 μm and a softening point of 250° C.

2. Preparation of Low Temperature-Sintering Rear Silver Paste

The present invention provides a low temperature-sintering rear silver paste for an all-aluminum back surface field crystalline silicon solar cell for reducing recombination of current carriers and formation of silver-aluminum alloy, the process of which features simplified procedures and is suitable for the existing process flow. The low temperature-sintering rear silver paste was prepared from the following components in part by mass:

| | | | |
|---|---|---|---|
| i. | a nano-silver powder | 69.8 | parts; |
| ii. | texanol | 10 | parts; |
| iii. | ethyl cellulose | 10 | parts; |
| iv. | sorbitan trioleate | 0.05 | parts; |
| v. | TDO | 0.05 | parts; |
| vi. | hydrogenated castor oil | 0.05 | parts; and |
| vii. | polyamide wax | 0.05 | parts; |

wherein the nano-silver powder has a tap density of 3.5 g/cm³, a specific surface area of 5.8 cm²/g, a median particle size D₅₀ of 0.5 μm, a span of the particle size of 0.9, and a loss on ignition of 0.2%. The above nano-silver powder, texanol, ethyl cellulose, sorbitan trioleate, TDO, hydrogenated castor oil and polyamide wax were well mixed according to the ratios, and ground and dispersed such that the fineness of the paste did not exceed 15 μm.

3. Preparation of Rear Electrode of PERC Solar Cell

Metallization of the rear electrode was performed by using the low temperature-sintering rear silver paste prepared above. Double-sided texturing was first performed on the front and the rear of a P-type crystalline silicon by using acid or base;

a silicon nitride anti-reflection passivation coating was then formed on the front of the P-type crystalline silicon;

a rear passivation layer was then plated on the rear of the P-type crystalline silicon, and by using SiNₓ or Al₂O₃ a passivation layer was formed on the rear of the cell as a rear reflector for increasing absorption of long wave light and for maximizing the potential difference between P-N electrodes to reduce electron recombination, so as to improve the conversion efficiency of the cell;

grooving was then performed on the rear passivation layer, and prior to metallization, coating opening following a specific pattern was performed on the rear passivation coating by using laser to remove part of the passivation layer; by using such local point contact mode, the electrode contact area and thus the electrode recombination could be reduced;

the front and the rear of the P-type crystalline silicon were then metallized separately, wherein the metallization of the rear of the P-type crystalline silicon comprised the following steps:
(1) an aluminum paste was printed on the rear passivation layer of the P-type crystalline silicon and dried, and the silver paste was then printed on the front, and dried and sintered, wherein for the rear aluminum paste, the drying temperature was 250° C., and the drying time period was 3.5 min; for the front silver paste, the drying temperature was 250° C., the drying time period was 2.5 min, the sintering temperature was 750° C., and the sintering time period was 15 s; and
(2) the low temperature-sintering rear silver paste was printed on the rear aluminum paste according to the step (1), dried and sintered to form a rear silver electrode, wherein for the above rear electrode, the drying temperature was 250° C., the drying time period was 2.5 min, the sintering temperature was 400° C., the width was 2.5 mm, the length was 20 mm, and the height was 5 μm.

### Comparative Example 1

10 parts of a spherical silver powder having a particle size D₅₀ of 0.8 μm, 60 parts of a flake silver powder having a particle size D₅₀ of 4.0 μm, 20 parts of bisphenol A epoxy resin E51, 8.3 parts of active diluent butanediol diglycidyl ether, 1.18 parts of curing agent dicyandiamide, 0.02 parts of curing accelerator 2-methylimidazole and 0.5 parts of thixotropic auxiliary agent fumed silica by mass were well mixed in a planetary mixer with rotation and revolution functions. The well-mixed materials were ground and dispersed on a three-roll mill according to a certain process to give a fine and uniform paste free of coarse particles. After testing, the fineness was less than 10 μm and the viscosity was 46 Pa·S. The above paste was further sieved through a 200-mesh sieve, packaged, and stored at −5° C. for later use.

On a crystalline silicon solar cell production line, firstly, according to the production process flow of a conventional solar cell, after the standard starting material, a monocrystalline silicon die having a size of 156 mm×156 mm and a thickness of 180 μm, was subjected to cleaning and texturing, p-n junctions were prepared by diffusion, and the phosphosilicate glass (PSG) layer was removed by etching; after the silicon die was configured into a blue film plate by plating an anti-reflection coating by PECVD, the blue film plate was first fully printed with the rear aluminum paste by screen printing, dried, printed with the front silver paste, dried, sintered at high temperature for a short time according to the sintering process of cell plates to form an aluminum back surface field and front silver electrodes, printed with the above paste and cured in a dryer at 150° C. for 30 min to form rear silver electrodes.

### Comparative Example 2

20 parts of a spherical silver powder having a particle size D₅₀ of 2.0 μm, 60 parts of a flake silver powder having a particle size D₅₀ of 2.8 μm, 14 parts of bisphenol A epoxy resin E51, 5 parts of active diluent phenyl glycidyl ether, 0.77 parts of curing agent dicyandiamide, 0.03 parts of curing accelerator 2-ethyl-4-methylimidazole and 0.2 parts of thixotropic auxiliary agent polyamide wax by mass were well mixed in a planetary mixer with rotation and revolution functions. The well-mixed materials were ground and dispersed on a three-roll mill according to a certain process to give a fine and uniform paste free of coarse particles. After testing, the fineness was less than 12 μm and the viscosity was 34 Pa·S. The above paste was further sieved through a 200-mesh sieve, packaged, and stored at −5° C. for later use.

The above paste was subjected to the process flow of Comparative Example to give a cell plate, wherein the baking and curing temperature of the rear silver paste was 200° C., and the time period was 10 min.

The performance analysis of the present invention is as follows:

The cell plates prepared in Examples 1 to 3 and Comparative Examples 1 and 2 were tested after sintering for their electric properties, which are shown in Table 1.

TABLE 1
Electric properties

| | Open-circuit | Short-circuit | Series | Parallel | | Conversion |
|---|---|---|---|---|---|---|
| | voltage | current | resistance | resistance | Fill factor | efficiency |
| Item | (V) | (A) | (Ω) | (Ω) | (%) | (%) |
| Example 1 | 0.6900 | 9.958 | 0.0021 | 2570 | 81.66 | 21.52 |
| Example 2 | 0.6880 | 9.960 | 0.0017 | 2658 | 81.97 | 21.46 |
| Example 3 | 0.6840 | 9.961 | 0.0019 | 2594 | 81.78 | 21.55 |
| Comparative Example 1 | 0.6821 | 9.415 | 0.0035 | 2651 | 78.21 | 21.35 |
| Comparative Example 2 | 0.6802 | 9.6521 | 0.0021 | 2702 | 80.56 | 21.17 |

As can be seen from the table above, in the preparation of rear electrodes by using the conductive silver paste disclosed herein, silver and aluminum can be effectively prevented from mutual diffusion to form silver-aluminum alloy and the welding performance can be improved; the rear silver paste is printed on the rear aluminum layer to form a layer in the rear silver region, which can increase the contact area between the rear silver paste and the aluminum paste, thereby increasing the open-circuit voltage of the solar cell prepared, reducing the lap resistance of silver and aluminum and thus improving the photoelectric conversion efficiency of the cell.

Finally, it should be noted that the above examples are only for illustrating the technical schemes of the present invention but not for limiting the protection scope of the present invention. Although the present invention is described in detail with reference to the preferred schemes, it should be understood by those skilled in the art that modifications or equivalent substitutions can be made to the technical schemes of the present invention without departing from the spirit and scope of the technical schemes of the present invention.

What is claimed is:

1. A low temperature-sintering rear silver paste for an all-aluminum back surface field crystalline silicon solar cell, comprising the following components in part by mass:

| | | |
|---|---|---|
| a nano-silver powder | 50-70 | parts; |
| an organic vehicle | 20-50 | parts; |
| a dispersant | 0.1-0.3 | parts; and |
| a thixotropic agent | 0.1-0.3 | parts; |

wherein the nano-silver powder has a tap density of 3-3.5 g/cm³, a specific surface area of 4.8-5.8 cm²/g, a median particle size D₅₀ of 0.05-0.5 μm, a span of the particle size of 0.8-0.9, and a loss on ignition of 0.1-0.2%.

2. The low temperature-sintering rear silver paste for an all-aluminum back surface field crystalline silicon solar cell according to claim 1, further comprising 1-10 parts by mass of a glass powder.

3. The low temperature-sintering rear silver paste for an all-aluminum back surface field crystalline silicon solar cell according to claim 2, wherein the glass powder has a softening point of 250-350° C., and a median particle size D₅₀ of 0.3-0.4 μm.

4. The low temperature-sintering rear silver paste for an all-aluminum back surface field crystalline silicon solar cell according to claim 2, wherein the glass powder comprises, in part by mass, 60-65 parts of Pb₃O₄, 10-20 parts of B₂O₃, 5-10 parts of ZnO or Zn₃(PO₄)₂, 1-10 parts of SiO₂, 1-3 parts of Al₂O₃, 1-3 parts of NiO and 2-5 parts of V₂O₅.

5. The low temperature-sintering rear silver paste for an all-aluminum back surface field crystalline silicon solar cell according to claim 1, wherein the organic vehicle is selected from one or a mixture of more selected from ethyl cellulose, terpineol, butyl carbitol, butyl carbitol acetate and texanol.

6. The low temperature-sintering rear silver paste for an all-aluminum back surface field crystalline silicon solar cell according to claim 1, wherein the dispersant is one or a mixture of more selected from DMA, TDO, sorbitan trioleate, BYK-110 and BYK-111.

7. The low temperature-sintering rear silver paste for an all-aluminum back surface field crystalline silicon solar cell according to claim 1, wherein the thixotropic agent is selected from hydrogenated castor oil and polyamide wax, or a mixture thereof.

8. A method for preparing a rear silver electrode of a PERC solar cell by using the low temperature-sintering rear silver paste for an all-aluminum back surface field crystalline silicon solar cell according to claim 1, comprising forming a silicon nitride anti-reflection passivation coating on a front of a P-type crystalline silicon, plating a rear passivation layer on a rear of the P-type crystalline silicon, grooving on the rear passivation layer, and metallizing the front and the rear of the P-type crystalline silicon, wherein metallizing the rear of the P-type crystalline silicon comprises the following steps:
(1) printing an aluminum paste on the rear passivation layer of the P-type crystalline silicon and drying, then printing a silver paste on the front and drying, and sintering; and
(2) printing the low temperature-sintering rear silver paste on the rear aluminum paste according to the step (1), drying and sintering to form a rear silver electrode.

9. The method according to claim 8, wherein for the rear aluminum paste in step (1), the drying temperature is 150-250° C., and the drying time period is 2.5-3.5 min; for the front silver paste, the drying temperature is 150-250° C., the sintering temperature is 750-850° C., and the sintering time period is 8-15 s.

10. The method according to claim 8, wherein for the rear electrode in step (2), the drying temperature is 150-250° C., the drying time period is 1.5-2.5 min, the sintering temperature is 250-400° C., the width is 0.6-2.5 mm, the length is 8-20 mm, and the height is 2-5 μm.
